(19) United States
(12) Patent Application Publication
(10) Pub. No.: US 2026/0133612 A1
(43) Pub. Date: May 14, 2026

(54) ELECTRONIC DEVICE DOCKING STATION WITH COOLING SYSTEM FOR HEAT DISSIPATION OF DOCKED ELECTRONIC DEVICE, AND RELATED METHODS

(71) Applicant: QUALCOMM Incorporated, San Diego, CA (US)

(72) Inventors: Dhinesh Jambai Gopu, Bengaluru (IN); Abhith M, Bengaluru (IN)

(21) Appl. No.: 18/945,389

(22) Filed: Nov. 12, 2024

(51) Int. Cl. G06F 1/20; G06F 1/16; H05K 7/20

(52) U.S. Cl. CPC G06F 1/203; G06F 1/1632; H05K 7/20272; H05K 7/2039; G06F 2200/201

(57) ABSTRACT

Electronic device docking station (“docking station”) with cooling system for heat dissipation of docked electronic device, and related methods of docking an electronic device into the docking station. The docking station includes a heat dissipation device in the form of a metal plate that extends from a rear member of the housing of the docking station. The metal plate is configured to be received (either fully or partially) within an internal cavity of an electronic device when the electronic device is disposed on the platform of the housing to be docked in the docking station. In this manner, when the electronic device is disposed on the platform of the docking station housing and docked to the docking station, the metal plate is located in proximity to and thermally coupled to electronic circuits within the electronic device that generate heat. The metal plate dissipates heat generated by the docked electronic device.

### TECHNICAL FIELD

The field of the disclosure relates to cooling systems for electronic devices, such as laptop computers, to dissipate heat.

### BACKGROUND

An electronic device can include one or more IC chips and other related circuits mounted on and electrically coupled to a substrate, such as a printed circuit board (PCB). These chips and circuits consume power in operation. It is common for electronic devices that have more sophisticated functionality to include a processor that is packaged as an IC chip and is configured to interface with other external circuits, such as memory in other IC chips and/or circuits on a PCB. The processor may also be included in system-on-a-chip (SoC) that also includes other supporting circuity within a single IC chip. A processor is typically a higher power consuming device. Heat is generated by the processor and other IC chips and circuits in an electronic device as a result of energy losses from the powered operation of the circuits. As the circuitry of an electronic device becomes more powerful in terms of increases in functionality and operational speeds as well as becoming more compact in size, the IC chips and circuits in the electronic device generate an increasing amount of heat due to the high-speed electron flow. Excessive heat can increase the junction temperature of IC chips and circuits and degrade their performance and reliability, and in extreme cases causes circuitry to fail due to exceeding its thermal limit. An IC chip may also have a temperature limitation for operation based on its circuit performance criteria (e.g., a circuit will have a thermal limit at which performance starts to decrease), to extend battery life, and/or to maintain temperature within “skin limits.”

Thus, it is important to provide cooling mechanisms to maintain temperature in an electronic device within desired limits based on its heat generation. It is particularly important to maintain temperature in a laptop computer for example, because the IC chips and other circuits are packaged in a relatively small form factor, yet generate excessive heat due to higher performance. Laptop computers include cooling mechanisms such as fans and heat sinks to dissipate heat; however, these cooling mechanisms may be inefficient or become clogged with dirt or dust from their environment, thus causing the laptop computer to overheat and/or performance to be reduced to reduce temperature. Laptop computers may also be more frequently used in environments that have higher ambient temperatures, including outdoor use, that in turn increase the baseline temperature of the laptop computer, as opposed to desktop computers for example more often used in indoor environments. This increased baseline temperature combined with internal heat generation can increase the likelihood of the laptop computer overheating and either damaging circuits or reducing performance. Laptop computers are also increasingly being used for intensive workloads (e.g., gaming, video editing) that consume more power and thus cause even more excess heat generation. Increasing performance in laptop computers that outpaces the heat dissipation of cooling mechanisms also causes excess heat generation that can lead to increased failures and/or reduced performance.

### SUMMARY

Aspects disclosed in the detailed description include an electronic device docking station with a cooling system for heat dissipation of a docked electronic device. Related methods of docking an electronic device into the electronic device docking station for heat dissipation are also disclosed. An electronic device docking station (“docking station”) is a housing that includes a platform to physically support docking of an electronic device. The housing also includes internal docking electrical connectors configured to be coupled with complementary electrical connectors of the electronic device when the electronic device is docked on the platform, to provide connectivity between external docking connectors of the docking station and the electrical connectors of the electronic device. For example, the docking station may be a laptop computer docking station that is configured to dock a laptop computer and provide connectivity between electrical connectors of the laptop (e.g., external display connector, keyboard connector, power connector, data connector (e.g., universal serial bus (USB)) connector) and like kind internal docking connectors of the docking station. The internal docking connectors are fixedly connected to like kind external docking connectors that are externally accessible from the docking station and are configured to be connected to external devices (e.g., external display, external keyboard, power supply, etc.). In this manner, cables connected to the external docking connectors do not have to be unconnected and reconnected each time the electronic device is docked and undocked, to provide connectivity between the electronic device and connected to the external docking connectors.

In exemplary aspects, the docking station includes a heat dissipation device in the form of a metal plate (also referred to as “cold plate”) that extends from a rear member of the housing of the docking station. The metal plate is configured to be received (either fully or partially) within an internal cavity of an electronic device when the electronic device is disposed on the platform of the housing to be docked in the docking station. In this manner, when the electronic device is disposed on the platform of the docking station housing and docked to the docking station, the metal plate is located in proximity to and thermally coupled to electronic circuits within the electronic device that generate heat. The metal plate dissipates heat generated by the electronic device. In this manner, the metal plate provides a cooling mechanism for a docked electronic device beyond whatever internal cooling mechanisms are included in the electronic device itself. For example, the electronic device may be capable of higher performance when executing higher intensity workloads and under higher ambient temperature conditions when docked to the docking station through the heat dissipation provided by the metal plate of the docking station. This additional cooling mechanism provided by the docking station may also cause internal cooling mechanisms of the docked electronic device to operate more efficiently since the docking station also provides a cooling mechanism for the docked electronic device. For example, a fan provided in the electronic device may not have to operate at higher fan speeds to maintain temperature of the electronic device as would otherwise be required if the docking station did not provide an additional cooling mechanism for the electronic device.

In another exemplary aspect, a portion of the metal plate may extend outside of the internal cavity of the electronic device when it is docked to the docking station to provide an expanded area of the metal plate. In this manner, the expanded external area of the metal plate of the docking connector provides additional heat dissipation capability for a docked electronic device. The expanded external area of the metal plate also provides a platform in which the additional cooling device is disposed to facilitate enhanced dissipation of heat generated by the electronic device conducted by the metal plate.

In yet another exemplary aspect, the heat dissipation device also includes a cooling device (e.g., a liquid transfer tube, a heat sink) thermally coupled to the metal plate to dissipate heat conducted by the metal plate from the electronic device. In this manner, the additional cooling device can provide for the heat conducted by the metal plate from a docked electronic device to be dissipated faster, thus enhancing the cooling performance provided by the heat dissipation device of the docking station.

In yet another exemplary aspect, the cooling device thermally coupled to the metal plate includes a liquid cooling device. The liquid cooling device is configured to carry a liquid thermally coupled to the metal plate to dissipate heat conducted by the metal plate and is configured to transport the liquid that is thermally coupled to the metal plate to further assist in dissipating heat from the metal plate for enhanced cooling. For example, the liquid cooling device can be a liquid transfer tube in contact with a surface of the metal plate and can be formed as a partial loop. The liquid transfer tube can include an inlet configured to receive the liquid in a cooled state that is then transported through the heat pipe and heated by the thermally conducted dissipated heat from the metal plate to an outlet in a heated state. In this manner, the inlet and outlet of the liquid transfer tube can be coupled to a respective outlet and inlet of an external liquid cooling station that is configured to pump liquid in the cooled state to the inlet of the liquid transfer tube and receive returned liquid in the heated stated as a result of heat dissipation from the metal plate. The returned liquid can be re-cooled by the liquid cooling station and then pumped back through its outlet to be received in the inlet of the liquid transfer tube in the cooled state in a continuous cycle.

In this manner, in this example, the docking station can support indirect liquid cooling of a docked electronic device for even more enhanced heat dissipation and cooling of the electronic device. For example, if the docking station is set up on a desk, the external liquid cooling station can be located in close proximity (e.g., on the desk or underneath the desk) with its outlet and inlet tubes coupled to the respective inlet port and outlet port of the liquid thermal interface of the docking station.

In yet another exemplary aspect, the cooling device thermally coupled to the metal plate is a heat sink. For example, the heat sink may be coupled to a portion of the metal plate that extends outside of the internal cavity of a docked electronic device. Thus, when an electronic device is docked and receives the metal plate, both the metal plate and the heat sink are thermally coupled to the electronic device to provide enhanced heat dissipation from the electronic device as a cooling mechanism. Because the heat sink is external to metal plate, there is more freedom to design the heat sink with features that do not need to be capable of being received in the internal cavity of a docked electronic device. For example, the heat sink may include one or more metal fins that extend upward in a direction away from the platform to provide enhanced heat dissipation. In this manner, the heat sink provides additional heat dissipation of heat thermally conducted by the metal plate when an electronic device is docked to the docking station and receives the metal plate within its internal cavity.

In this regard, in one exemplary aspect, a docking station is disclosed. The docking station includes a housing comprising a platform configured to support an electronic device, and a rear member that extends upward from a rear side of the platform. The docking station also includes a heat dissipation device. The heat dissipation device includes a metal plate that extends from the rear member of the housing towards the platform. The metal plate is configured to be at least partially disposed in an internal cavity of an electronic device disposed on the platform to thermally couple the metal plate to the electronic device.

In another exemplary aspect, a system is disclosed. The system includes an electronic device comprising an internal cavity. The system also includes a docking station. The docking station includes a housing comprising a platform configured to support an electronic device, and a rear member that extends upward from a rear side of the platform. The docking station also includes a heat dissipation device. The heat dissipation device includes a metal plate that extends from the rear member of the housing towards the platform. The metal plate is configured to be at least partially disposed in the internal cavity of the electronic device disposed on the platform to thermally couple the metal plate to the electronic device.

In another exemplary aspect, a docking station system is disclosed. The docking station system includes docking station. The docking station includes a housing comprising a platform configured to support an electronic device, and a rear member that extends upward from a rear side of the platform. The docking station also includes a heat dissipation device. The heat dissipation device includes a metal plate that extends from the rear member of the housing towards the platform. The metal plate is configured to be at least partially disposed in an internal cavity of an electronic device disposed on the platform to thermally couple the metal plate to the electronic device. The heat dissipation device also includes a liquid cooling device coupled to the metal plate, the liquid cooling device configured to carry a liquid thermally coupled to the metal plate to dissipate heat conducted by the metal plate. The docking station system also includes a liquid cooling station. The liquid cooling station includes a liquid reservoir configured to store the liquid. The liquid cooling station also includes a cooling device configured to cool the liquid in the liquid reservoir. The docking station system also includes a pump coupled to the liquid reservoir. The pump is configured to pump the liquid in a cooled state from the liquid reservoir to the liquid cooling device. The pump is also configured to receive the liquid in a heated state from the liquid cooling device.

### BRIEF DESCRIPTION OF THE DRAWINGS

FIGS. 1A-1-1A-2 are a right-side rear perspective view and a close-up right-side perspective view, respectively, of an exemplary docking station that includes a housing with a platform configured to support an electronic device, wherein the docking station also includes a heat dissipation device in the form of a metal plate configured to be at least partially received by an internal cavity of an electronic device disposed on the platform and docked/to be docked in the docking station, to dissipate heat generated by the electronic device;

FIGS. 1B and 1C are front perspective views of the docking station in FIGS. 1A-1-1A-2 disposed on a table with and without a docked electronic device;

FIG. 1D is a cross-sectional side view of the docking station in FIGS. 1A-1-1A-2;

FIG. 1E is a perspective view of the metal plate of the heat dissipation device in the docking station in FIGS. 1A-1-1A-2 received in an internal cavity of an electronic device docked in the docking station;

FIG. 1F is a rear perspective view of the docking station in FIGS. 1A-1-1A-2;

FIG. 2A is a right-side rear perspective views of another exemplary docking station that is similar to the docking station in FIGS. 1A-1-1F, but wherein the heat dissipation device additionally includes a liquid cooling device thermally coupled to the metal plate, wherein the liquid cooling device is configured carry liquid received from an external liquid cooling station in a cooled state, to be thermally coupled to the metal plate and returned to the liquid cooling station in a heated state and then re-cooled, to further assist in dissipating heat from the metal plate for enhanced cooling;

FIG. 2B is a cross-sectional side view of the docking station in FIG. 2A;

FIG. 2C is a side perspective view of the heat dissipation device in the docking station in FIG. 2A illustrating a liquid transfer tube coupled to a metal plate;

FIGS. 2D and 2E are front perspective views of the docking station in FIG. 2A disposed on a table with and without a docked electronic device;

FIGS. 3A and 3B are right-side rear perspective and side views of the docking station in FIGS. 2A-2E illustrating a latching mechanism provided in the docking station to secure an electronic device in the docking station when docked;

FIG. 3C is a side view of the latch mechanism of the docking station in FIGS. 1A-1-1F and 2A-2E in an unlocked state and configured to releasably lock a front retaining member of the docking station to the platform of the docking station to retain a docked electronic device to the platform;

FIG. 3D is a side view of the latch mechanism in FIG. 3C in a locked state to secure the front retaining member of the docking station abutted to the platform of the docking station;

FIG. 3E is a side perspective view of the front retaining member of the docking station in FIGS. 3A-3D configured to engage with an electronic device to secure the electronic device on the platform when the latch mechanism is in a locked state as shown in FIG. 3D;

FIG. 3F is a side cross-sectional view of the front retaining member of the docking station in FIGS. 3A-3E abutted to the platform with the latching mechanism in a locked state securing the electronic device on the platform;

FIGS. 4A and 4B are front, side perspective and side views of the docking station in FIG. 1A-1-1F or 2A-2E, further illustrating rollers in the top surface of the platform to facilitate the insertion and traversing of an electronic device on the platform in the docking station;

FIG. 5A is a side perspective view of an alternative heat dissipation device that can be employed in a docking station like the docking station in FIGS. 1A-1-1F, wherein the heat dissipation device includes an external heat sink thermally coupled to the metal plate to provide enhanced heat dissipation for a docked electronic device;

FIGS. 5B and 5C are side and close-up side views of the external heat sink of the heat dissipation device in FIG. 5A;

FIGS. 5D and 5E are side perspective and front views of the external heat sink of the heat dissipation device in FIG. 5A;

FIG. 6 is a flowchart illustrating an exemplary process of docking an electronic device in a docking station that includes a heat dissipation device in the form of a metal plate configured to be at least partially received by an internal cavity of an electronic device disposed on the platform and docked/to be docked in the docking station, to dissipate heat generated by the electronic device, including, but not limited to, the docking stations and heat dissipation devices in FIGS. 1A-1-5E;

FIG. 7 is a block diagram of an exemplary electronic device in the form of a processor-based system that can be configured to be docked in a docking station that includes a heat dissipation device in the form of a metal plate configured to be at least partially received by an internal cavity of an electronic device disposed on the platform and docked/to be docked in the docking station, to dissipate heat generated by the electronic device, including, but not limited to, the docking stations and heat dissipation devices in FIGS. 1A-1-5E; and

FIG. 8 is a block diagram of another exemplary electronic device in the form of wireless communications device that can be configured to be docked in a docking station that includes a heat dissipation device in the form of a metal plate configured to be at least partially received by an internal cavity of an electronic device disposed on the platform and docked/to be docked in the docking station, to dissipate heat generated by the electronic device, including, but not limited to, the docking stations and heat dissipation devices in FIGS. 1A-1-5E.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include an electronic device docking station with a cooling system for heat dissipation of a docked electronic device. Related methods of docking an electronic device into the electronic device docking station for heat dissipation are also disclosed. An electronic device docking station (“docking station”) is a housing that includes a platform to physically support docking of an electronic device. The housing also includes internal docking electrical connectors configured to be coupled with complementary electrical connectors of the electronic device when the electronic device is docked on the platform, to provide connectivity between external docking connectors of the docking station and the electrical connectors of the electronic device. For example, the docking station may be a laptop computer docking station that is configured to dock a laptop computer and provide connectivity between electrical connectors of the laptop (e.g., external display connector, keyboard connector, power connector, data connector (e.g., universal serial bus (USB)) connector) and like kind internal docking connectors of the docking station. The internal docking connectors are fixedly connected to like kind external docking connectors that are externally accessible from the docking station and are configured to be connected to external devices (e.g., external display, external keyboard, power supply, etc.). In this manner, cables connected to the external docking connectors do not have to be unconnected and reconnected each time the electronic device is docked and undocked, to provide connectivity between the electronic device and connected to the external docking connectors.

In exemplary aspects, the docking station includes a heat dissipation device in the form of a metal plate (also referred to as “cold plate”) that extends from a rear member of the housing of the docking station. The metal plate is configured to be received (either fully or partially) within an internal cavity of an electronic device when the electronic device is disposed on the platform of the housing to be docked in the docking station. In this manner, when the electronic device is disposed on the platform of the docking station housing and docked to the docking station, the metal plate is located in proximity to and thermally coupled to electronic circuits within the electronic device that generate heat. The metal plate dissipates heat generated by the electronic device. In this manner, the metal plate provides a cooling mechanism for a docked electronic device beyond whatever internal cooling mechanisms are included in the electronic device itself. For example, the electronic device may be capable of higher performance when executing higher intensity workloads and under higher ambient temperature conditions when docked to the docking station through the heat dissipation provided by the metal plate of the docking station. This additional cooling mechanism provided by the docking station may also cause internal cooling mechanisms of the docked electronic device to operate more efficiently since the docking station also provides a cooling mechanism for the docked electronic device. For example, a fan provided in the electronic device may not have to operate at higher fan speeds to maintain temperature of the electronic device as would otherwise be required if the docking station did not provide an additional cooling mechanism for the electronic device.

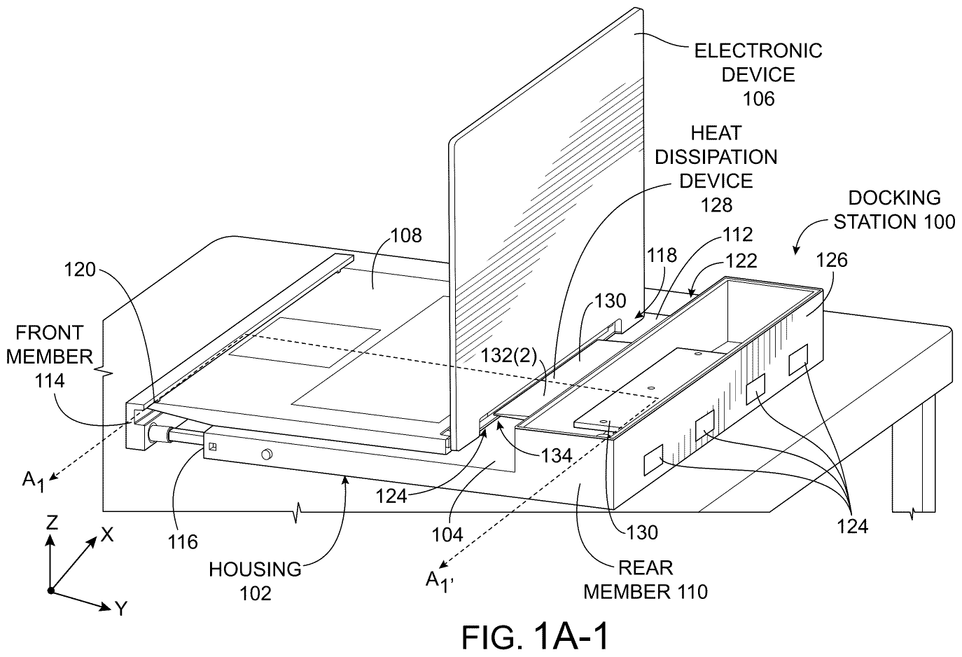

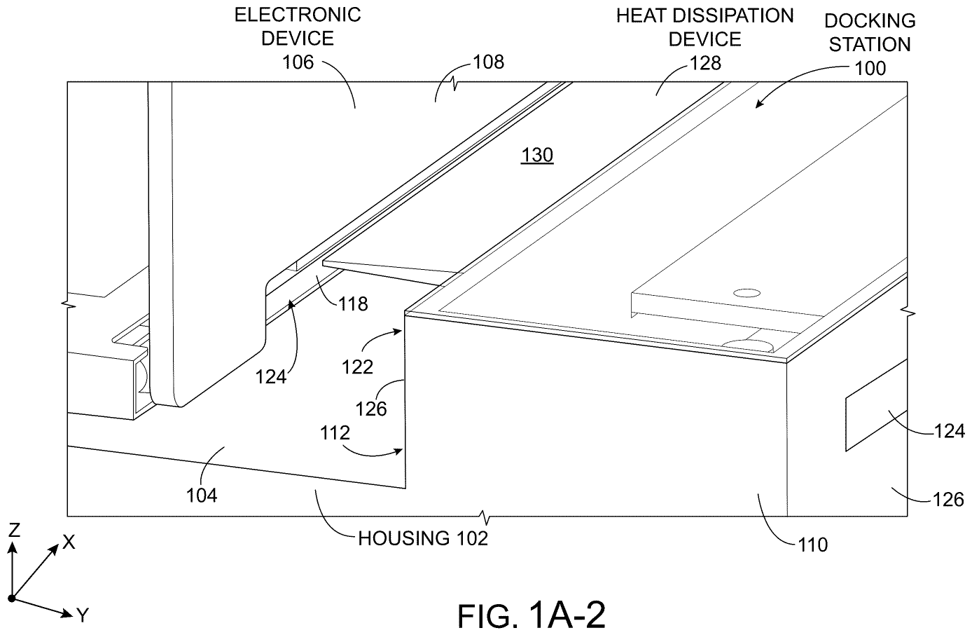

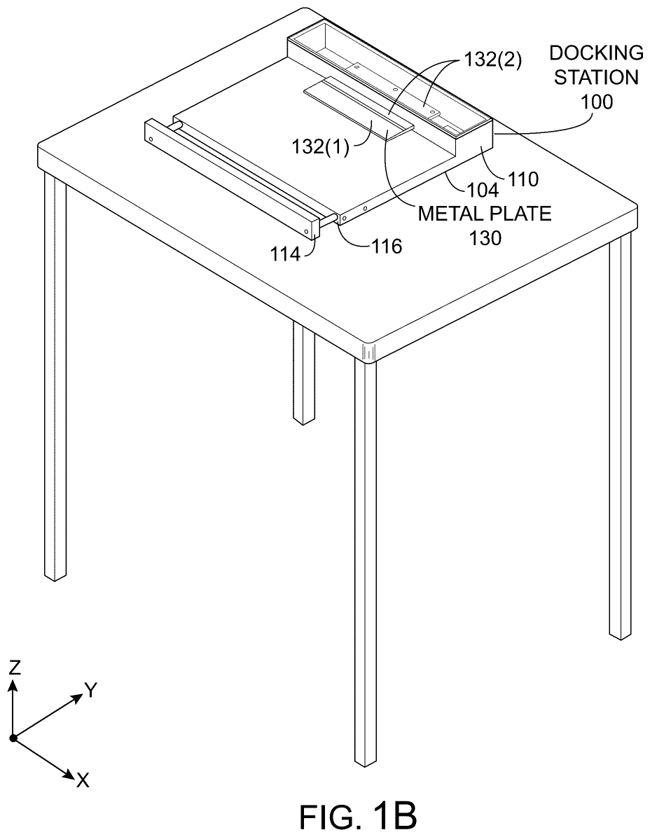

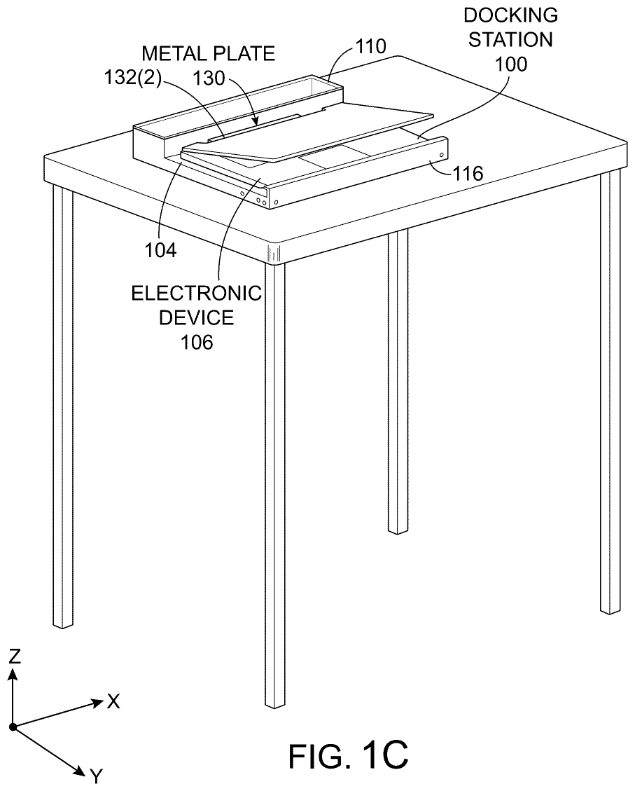

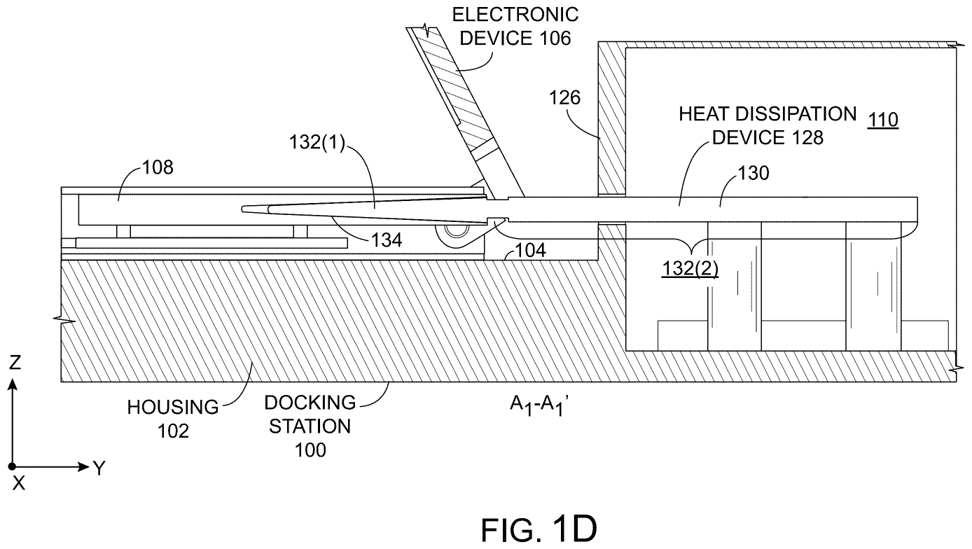

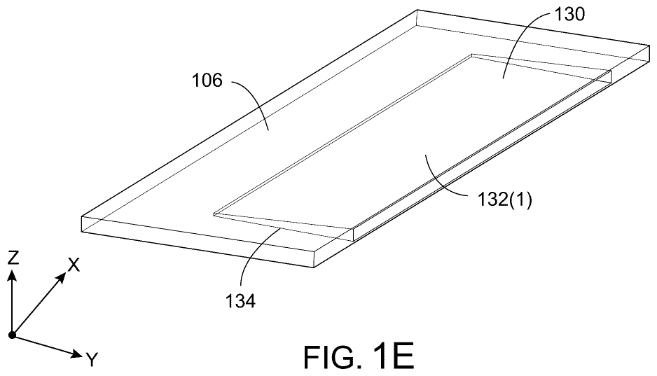

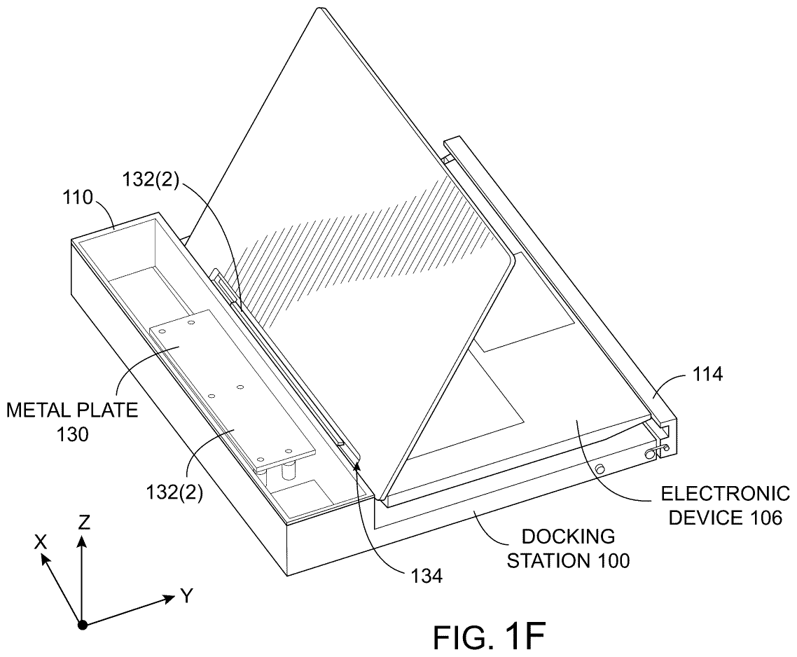

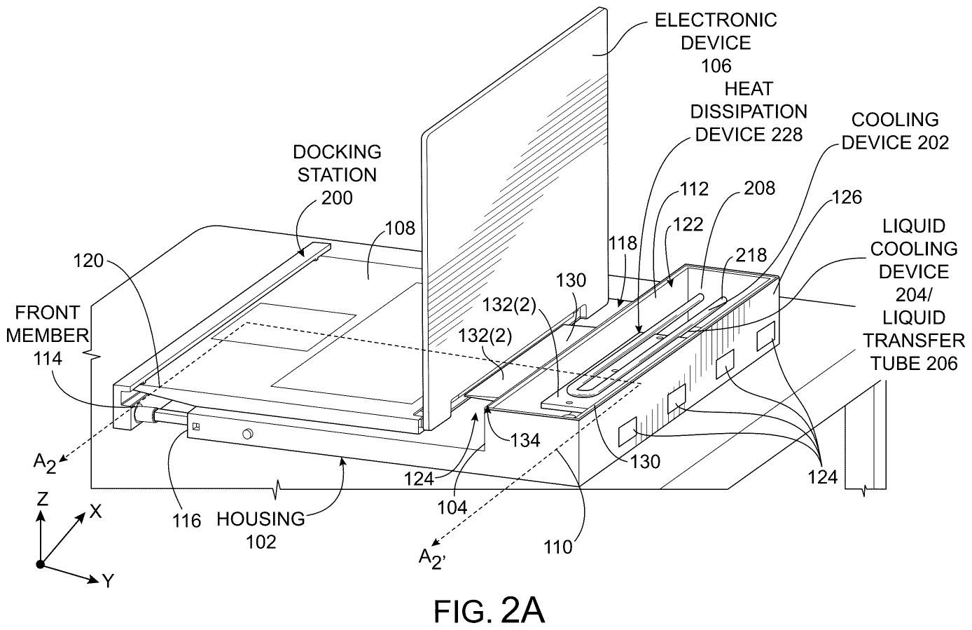

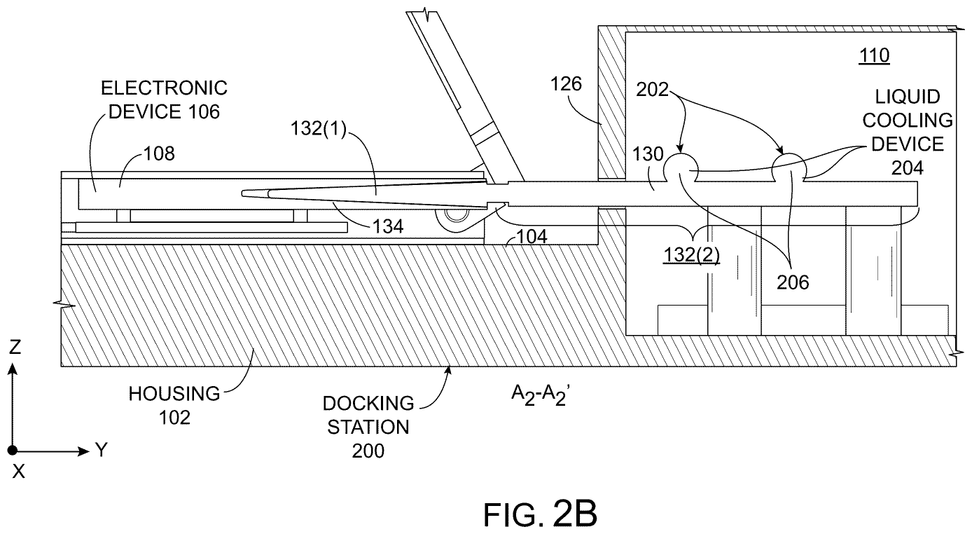

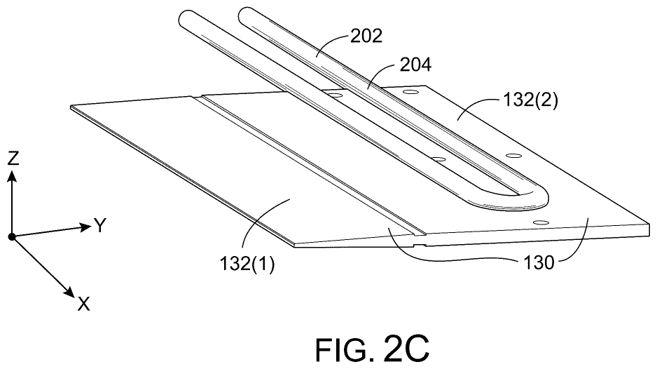

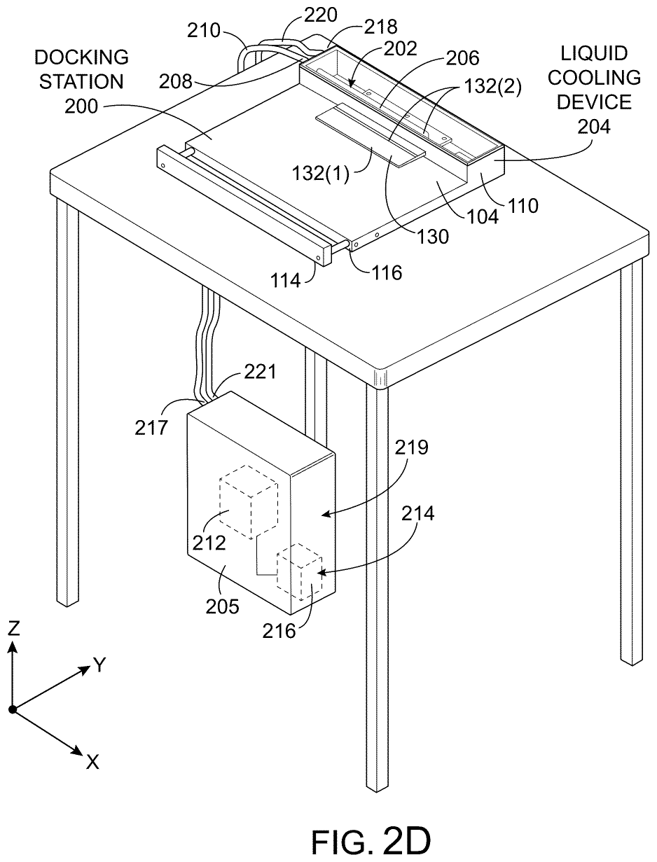

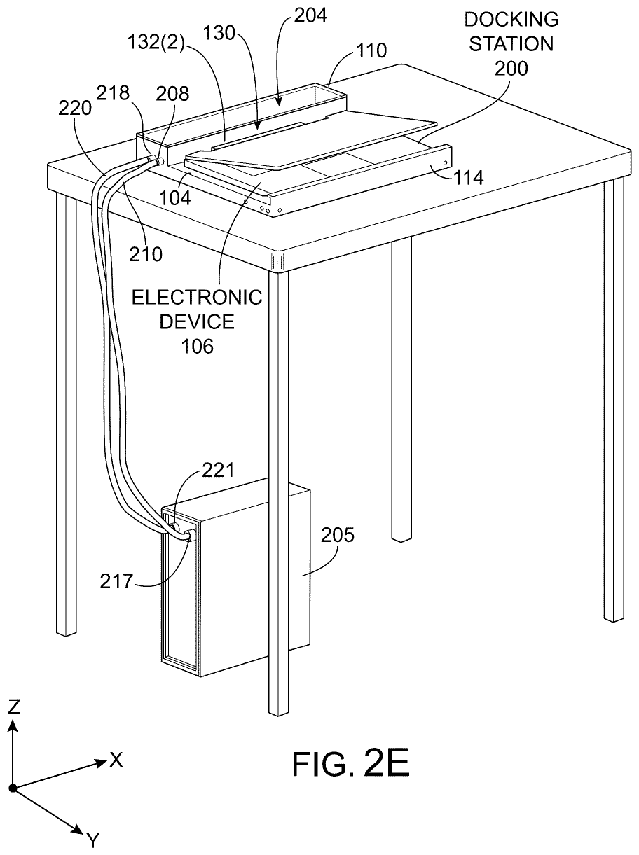

In this regard, FIGS. 1A-1 and 1A-2 are a right-side rear perspective view and a close-up right-side rear perspective view, respectively, of an exemplary docking station 100 that includes a housing 102 that has a platform 104 configured to support an electronic device 106. For example, the electronic device 106 disposed on the platform 104 of the docking station 100 is a laptop computer 108 in this example. The docking station 100 is configured to support the electronic device 106 to be docked in the housing 102. For example, the electronic device 106 is docked in the housing 102 by the electronic device 106 being disposed on the platform 104 of the housing 102 and secured within the housing 102. In this example, as shown in FIGS. 1A-1 and 1A-2, the housing 102 includes a rear member 110 that is disposed adjacent to a rear side 112 of the platform 104 and extends upward in a first, vertical direction (Z-axis direction) from the platform 104. As shown in FIG. 1A-1, the housing 102 also includes a front retaining member 114 that is coupled to a front side 116 of the platform 104 and is configured to slidably move transversely about the platform 104 in a second, horizontal direction (Y-axis direction) orthogonal to the first, vertical direction (Z-axis direction). In this manner, the docking station 100 is configured to secure the electronic device 106 on the platform 104 between the rear member 110 and the front retaining member 114.

FIG. 1B illustrates the docking station 100 ready to receive the electronic device 106 to be docked. To secure and “dock” the electronic device 106 in the docking station 100, the electronic device 106 is disposed on the platform 104 and a rear side 118 of the electronic device 106 is moved back towards the rear side 112 of the platform 104 and adjacent to the rear member 110 while the front retaining member 114 is pulled out away from the front side 116 of the platform 104, as shown in FIG. 1C. The front retaining member 114 is then moved back towards the front side 116 of the platform 104 to abut against a front side 120 of the electronic device 106 to secure the electronic device 106 on the platform 104 between the front retaining member 114 and the rear member 110.

With reference back to FIGS. 1A-1 and 1A-2, the rear member 110 of the housing 102 of the docking station 100 also includes internal electrical docking connectors 122 that are electrical connectors (e.g., display port connector, power connector, bus connector (e.g., universal serial bus (USB) connector), etc.). In this manner, as part of the electronic device 106 being docked to the docking station, external electrical docking connectors 124 disposed on the rear side 118 of the electronic device 106 are mated with the internal electrical docking connectors 122 of the docking station 100. The internal electrical docking connectors 122 are coupled to the external electrical docking connectors 124 on a rear side 126 of the rear member 110. In this manner, cables connected to the external electrical docking connectors 124 of the docking station 100 are coupled to the electronic device 106 when docked to the docking station 100 via its external electrical docking connectors 124 being connected to the internal electrical docking connectors 122 of the docking station 100. Thus, each time the electronic device 106 is docked and un-docked from the docking station 100, the cables that are connected to the external electrical docking connectors 124 can remain connected with the electronic device 106 only being disconnected from the internal electrical docking connectors 122.

FIG. 1D is a cross-sectional side view of the docking station 100 along the A1-A1′ cross-sectional line in FIG. 1A-1. As shown in FIGS. 1A-1-1A-2 and 1D, to provide enhanced heat dissipation for the electronic device 106 as a cooling mechanism, the docking station 100 in this example includes a heat dissipation device 128. The heat dissipation device 128 in this example is a metal plate 130 that is partially retained in the rear member 110 and also extends from the rear side 126 of the rear member 110 of the housing 102 of the docking station 100 towards the platform 104. The metal plate 130 serves as a “cold plate,” and is made of a metal material (e.g., copper, aluminum, iron, metal alloy) that is configured to be a good thermal conductor of heat. As shown in FIGS. 1A-1 and 1D and discussed in more detail below, the metal plate 130 has a first metal plate portion 132(1) that is configured to be disposed in an internal cavity 134 of the electronic device 106 that is complementary to the first metal plate portion 132(1) when disposed on the platform 104 and docked. In this example, and as shown in detail in FIG. 1D, the first metal plate portion 132(1) has a triangular-shaped cross-sectional profile in a third, horizontal direction (X-axis direction) that is configured to mate securely within the internal cavity 134 of the electronic device 106 having a complementary triangular-shaped cross-sectional profile in the third, horizontal direction (X-axis direction). This is also shown in FIG. 1E which illustrates the first metal plate portion 132(1) of the metal plate 130 disposed within the internal cavity 134 of the electronic device 106. The metal plate has a second metal plate portion 132(2) that is configured to remain external from the internal cavity 134 of the of the electronic device 106 when disposed on the platform 104 and docked. In this example, the second metal plate portion 132(2) also extends internally into the rear member 110 to provide an expanded area of the metal plate 130 outside of the electronic device 106.

In this manner, internal electrical circuits and/or other heat generating devices in the electronic device 106 that generate heat when in operation are placed in close proximity to the first metal plate portion 132(1) of the metal plate 130 when the first metal plate portion 132(1) is disposed in the internal cavity 134 when the electronic device 106 is docked in the docking station 100. This is shown in FIG. 1F, which illustrates a rear perspective view of the docking station 100 with the electronic device 106 docked therein with the metal plate 130 of the heat dissipation device 128 disposed within the internal cavity 134 of the electronic device 106. In this regard, the first metal plate portion 132(1) is thermally coupled to the heat generating devices in the electronic device 106 and conducts heat generated by such heat generating devices to reduce the temperature of the electronic device 106. The heat conducted by the first metal plate portion 132(1) is also thermally conducted by the second metal plate portion 132(2) of the metal plate 130, which is disposed external to the electronic device 106. In this manner, the heat is thermally conducted away from the electronic device 106 to be dissipated in ambient air to act as a cooling mechanism for the electronic device 106 when docked in the docking station 100. In this example, the second metal plate portion 132(2) of the metal plate 130 also extends internally into the rear member 110 to provide an expanded area of the metal plate 130 outside of the electronic device 106 for enhanced heat dissipation.

The metal plate 130 of the heat dissipation device 128 of the docking station 100 provides a cooling mechanism for the docked electronic device 106 beyond whatever internal cooling mechanisms are included in the electronic device 106 itself. For example, the electronic device 106 may be capable of higher performance when executing higher intensity workloads and under higher ambient temperature conditions when docked to the docking station 100 through the heat dissipation provided by the metal plate 130 of the heat dissipation device 128 of the docking station 100. This additional cooling mechanism provided by the docking station 100 may also cause internal cooling mechanisms of the docked electronic device 106 to operate more efficiently since the docking station 100 also provides a cooling mechanism for the docked electronic device 106. For example, a fan provided in the electronic device 106 may not have to operate at higher fan speeds to maintain temperature of the electronic device 106 as would otherwise be required if the docking station 100 did not provide an additional cooling mechanism for the electronic device 106.

It may be desired to provide a docking station that has even greater cooling capability for a docked electronic device, including the docking station 100 in FIGS. 1A-1-1F. For example, it may be desired to provide a docking station that also has the capability for liquid cooling to enhance heat dissipation of a heat dissipation device, including the heat dissipation device 128 in the docking station 100 in FIGS. 1A-1D.

In this regard, FIG. 2A is a right-side rear perspective view of another exemplary docking station 200 that is similar to the docking station 100 in FIGS. 1A-1-1F. Common components between the docking station 100 in FIGS. 1A-1-1F and the docking station 200 in FIG. 2A are shown with common element numbers. The explanation of such common components above is applicable for the docking station 200 in FIG. 2A. However, the docking station 200 in FIG. 2A includes a heat dissipation device 228 that not only includes the metal plate 130 like in the docking station 100 in FIG. 1A-1D, but also includes an additional cooling device 202 that is also configured to dissipate heat conducted by the metal plate 130. In this example, the cooling device 202 is provided in the form of a liquid cooling device 204 that is thermally coupled to the metal plate 130. As discussed in more detail below, and as shown in FIGS. 2D and 2E, the liquid cooling device 204 is configured carry liquid received from an external liquid cooling station 205 in a cooled state, to be thermally coupled to the metal plate 130 and returned to the liquid cooling station 205 in a heated state and then re-cooled, to further assist in dissipating heat from the metal plate 130 for enhanced cooling.

In this regard, as shown in FIG. 2A and in the cross-section side view of the docking station 200 along the A2-A2′ cross-sectional line in FIG. 2B, the liquid cooling device 204 includes a liquid transfer tube 206 that is configured to carry liquid. As shown in FIGS. 2A and 2B, like the heat dissipation device 128 in the docking station 100 in FIGS. 1A-1-1F, the heat dissipation device 228 for the docking station 200 also includes the metal plate 130 that is partially retained in the rear member 110 and also extends from the rear side 126 of the rear member 110 of the housing 102 of the docking station 100 towards the platform 104. The metal plate 130 serves as a “cold plate,” and is made of a metal material (e.g., copper, aluminum, iron, metal alloy) that is configured to be a good thermal conductor of heat. Again, the metal plate 130 has a first metal plate portion 132(1) that is configured to be disposed in an internal cavity 134 of the electronic device 106 that is complementary to the first metal plate portion 132(1) when disposed on the platform 104 and docked. The metal plate 130 also has the second metal plate portion 132(2) that is configured to remain external to the internal cavity 134 of the of the electronic device 106 when disposed on the platform 104 and docked. In this example, the second metal plate portion 132(2) also extends internally into the rear member 110 to provide an expanded area of the metal plate 130 outside of the electronic device 106.

As shown in FIGS. 2A and 2B, the liquid transfer tube 206 is shown coupled to or integrated with the second metal plate portion 132(2) of the metal plate 130 such that liquid transferred through the liquid transfer tube 206 conducts heat from the metal plate 130 to heat the liquid and transfer such in a heated state back to the liquid cooling station 205 (see FIGS. 2D and 2E). The liquid transfer tube 206 can be thought of as a heat pipe in this example. In this example, the liquid transfer tube 206 is thermally coupled to the metal plate 130, and more particularly its second metal plate portion 132(2), by being integrated with the metal plate 130 as a single metal component. This is also shown in FIG. 2C which shows the liquid transfer tube 206 coupled to the second metal plate portion 132(2) of the metal plate 130. For example, the metal plate 130 may be formed such that the thermal transfer tube 206 is part of the mold used to fabricate the metal plate 130. Alternatively, the liquid transfer tube 206 could be a separate component that is physically attached to the metal plate 130, or indirectly attached through an intermediate component so long as the liquid transfer tube 206 is thermally coupled to the metal plate 130. In this example, the liquid transfer tube 206 is disposed internally into the rear member 110 of the housing 102 of the docking station 100. The liquid transfer tube 206 has an inlet 208 that is configured to receive liquid, and ideally in a cooled state.

FIGS. 2D and 2E illustrate the docking station 200 without and with an electronic device docked therein. As shown therein, the inlet 208 of the docking station 200 can be coupled to an inlet tube 210 that is coupled to the liquid cooling station 205. As shown in FIG. 2D, the liquid cooling station 205 may include a pump 212 that is configured to pump liquid 214 from a liquid reservoir 216 from a pump outlet 217 to the inlet tube 210 that will then be received by the inlet 208 of the liquid transfer tube 206. The liquid cooling station 205 may contain a cooling device 219, such as a condenser, to cool the liquid 214 in the liquid reservoir 216 so that the liquid 214 pumped to the inlet 208 of the liquid transfer tube 206 is in a cooled state. The liquid 214 will then be pumped through the liquid transfer tube 206 thermally coupled to the metal plate 130 in a loop as shown in FIG. 2A, and exit the liquid transfer tube 206 through its outlet 218. The liquid 214 will conduct heat dissipated by the metal plate 130 as it travels through the liquid transfer tube 206 on its way to the outlet 218 and be in a heated state, thereby providing additional heat dissipation to provide enhanced cooling for the docked electronic device 106. As shown in FIGS. 2D and 2E, the outlet 218 of the liquid transfer tube 206 is coupled to an outlet tube 220 coupled to a pump inlet 221 coupled to the pump 212 in the liquid cooling station 205. The liquid cooling station 205 is configured to pump the liquid 214 from the outlet 218 of the liquid transfer tube 206 in its heated state back to the liquid reservoir 216 through the pump inlet 221 to be cooled again and then pump the liquid 214 in the cooled state to be recycled back to the inlet 208 of the liquid transfer tube 206.

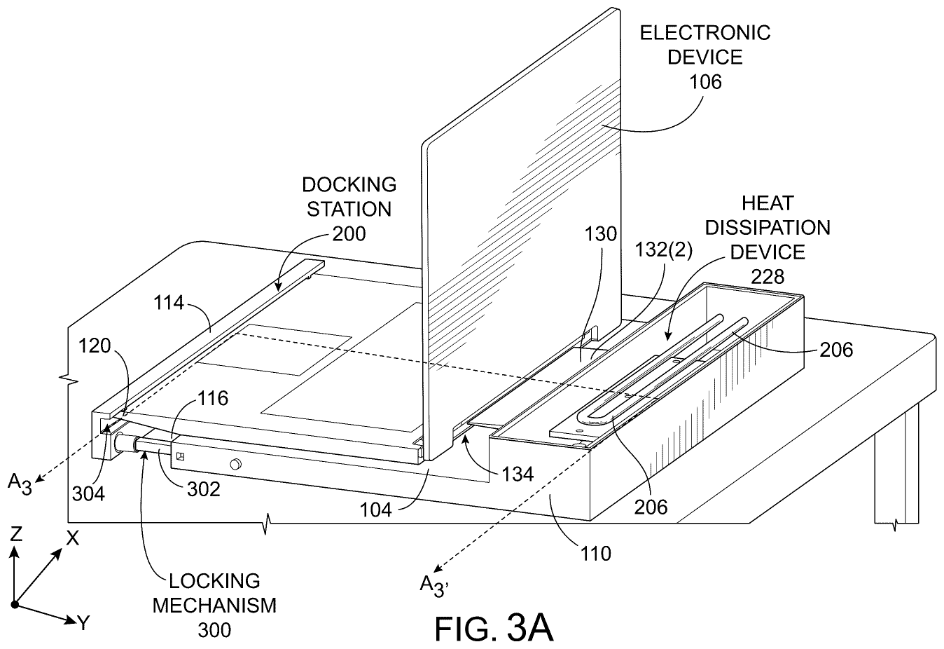

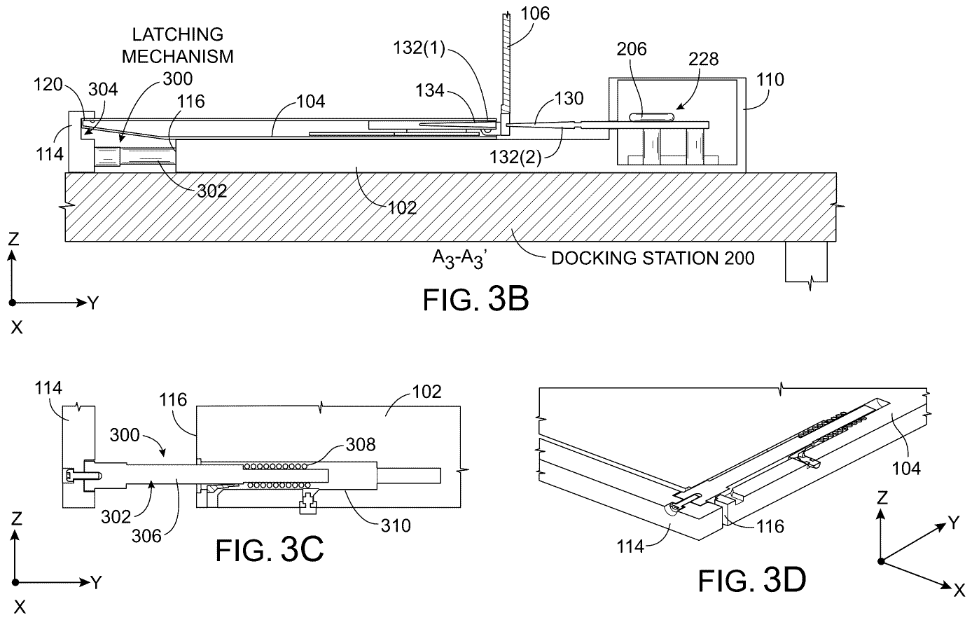

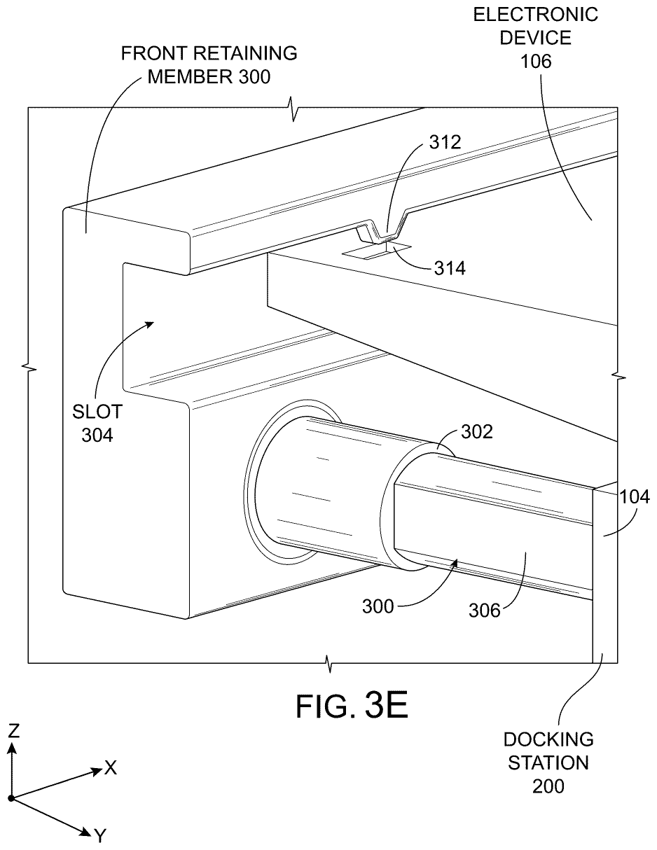

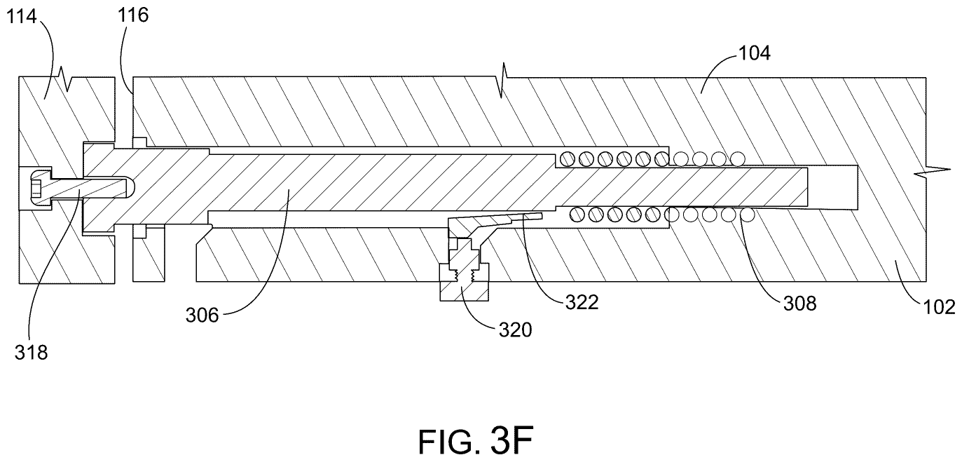

It may also be desired to provide a locking mechanism that can secure a docked electronic device, such as the electronic device 106 (e.g., see FIGS. 1A-1-1F and FIGS. 2A-2E), into the docking station 200 in FIGS. 2A-2E to provide a good thermal coupling between the electronic device and the heat dissipation device 228. In this regard, as discussed in more detail below, FIGS. 3A and 3B are right-side rear perspective and cross-sectional side views of the docking station 200 in FIGS. 2A-2E to illustrate a latching mechanism 300 provided in the docking station 200 to secure the electronic device 106 in the docking station 200 when docked. This securing of the electronic device 106 docked in the docking station 200 can also ensure good thermal coupling between the electronic device and the heat dissipation device 228. Note that although the latching mechanism 300 in FIGS. 3A-3B is provided in the docking station 200 in FIGS. 2A-2E, the latching mechanism 300 in FIGS. 3A and 3B could also be provided in the docking station 100 in FIGS. 1A-1-1F.

In this regard, FIG. 3A illustrates the electronic device 106 disposed on the platform 104 and not yet docked, with the internal cavity 134 of the electronic device 106 aligned with the metal plate 130, but the metal plate 130 not fully received in the internal cavity 134. FIG. 3B is a cross-section side view of the docking station 200 along the A3-A3′ cross-sectional line in FIG. 3A. As shown in FIGS. 3A and 3B, the latching mechanism 300 is a spring-loaded plunger 302 in this example. The spring-loaded plunger 302 is coupled to the front retaining member 114 of the docking station 200, and the front side 116 of the platform 104. The spring-loaded plunger 302 is configured to allow the front retaining member 114 of the docking station 200 to be traversed (i.e., movable) toward and away from the rear member 110 in the second, horizontal direction (Y-axis direction). The front retaining member 114 has a slot 304 that is configured to receive the front side 120 of the electronic device 106 disposed on the platform 104 to be docked in the docking station 200. In this manner, when the front retaining member 114 is moved back toward the rear member 110, the front retaining member 114 contacts and pushes on the front side 120 of the electronic device 106 to move the electronic device 106 and its internal cavity 134 back towards the metal plate 130 exposed from the rear member 110. The slot 304 in the front retaining member 114 assists in keeping the electronic device 106 secured to the platform 104 as the front retaining member 114 comes into contact with the electronic device 106 to move it back towards the rear member 110. When it is desired to undock the electronic device 106 from the docking station 200, the front retaining member 114 can be moved forward to allow the electronic device 106 to be moved forward towards the front retaining member 114 to remove the metal plate 130 from its internal cavity 134 to allow the electronic device 106 to be removed from the platform 104.

As discussed above, in this example, the latching mechanism 300 is a spring-loaded plunger 302. This is shown in more detail in the cross-sectional side view of the front retaining member 114 and the housing 102 of the docking station 200 in FIG. 3C. As shown in FIG. 3C, the spring-loaded plunger 302 includes a shaft 306 that is coupled to the front retaining member 114. The spring-loaded plunger 302 also includes a spring 308 that is disposed around the shaft 306 within a cavity 310 of the housing 102. This spring 308 provides a force towards the front retaining member 114 in its normal state to provide for the front retaining member 114 to not be closed towards the housing 102. However, as shown in FIG. 3D, when it is desired to retain the front retaining member 114 towards the housing 102 to secure the electronic device 106 on the platform 104, a force applied to the front retaining member 114 towards the rear member 110 will move the shaft 306 further into the cavity 310 of the housing 102 thus compressing the spring 308 within the cavity 310. As discussed in more detail below, the spring-loaded plunger 302 is configured to lock to the housing 102 to keep the front retaining member 114 secured adjacent to the platform 104 when the spring-loaded plunger 302 is fully engaged by the front retaining member 114 being pushed forward completely to abut the platform 104. The energy stored in the spring 308 will cause the front retaining member 114 to be released from the platform 104 to automatically move forward away from the platform 104 when the spring-loaded plunger 302 is unlocked from the platform 104, which would be performed to undock an docked electronic device 106.

For example, as shown in FIG. 3E, the front retaining member 114 may include a protrusion 312 that is configured to also be received within an opening 314 in the electronic device 106 when the front retaining member 114 is pushed toward the electronic device 106 on the platform 104. In this manner, the electronic device 106 is also physically coupled to the front retaining member 114. Thus, when the spring-loaded plunger 302 is unlocked from the platform 104, the energy stored in the spring 308 will cause the front retaining member 114 to pull the electronic device 106 forward away from the platform 104 to be undocked. This will also have the effect of moving the internal cavity 134 of the electronic device 106 away from the metal plate 130 so that the metal plate 130 is not an obstruction in removing the electronic device 106 from the platform 104 to undock the electronic device 106 from the docking station 200.

FIG. 3F is a side cross-sectional view of the front retaining member 114 of the docking station 200 in FIGS. 3A-3E abutted to the platform 104 with the latching mechanism 300 in a locked state. As shown therein, the shaft 306 of the spring-loaded plunger 302 is secured to the front retaining member 114 with a fastener 318 (e.g., a screw). The housing 102 includes a forward-biased latch 320 that allows the shaft 306 of the spring-loaded plunger 302 to be moved towards the platform 104, but the shaft 306 will interfere with an angled tab 322 of the latch 320 to keep the spring-loaded plunger 302 in a locked state. When it is desired to unlock the spring-loaded plunger 302, the forward-biased latch 320 can be adjusted to move the angled tab 322 out of interference with the shaft 306 to allow the energy stored in the spring 308 to be released to unlock the spring-loaded plunger 302 from the platform 104.

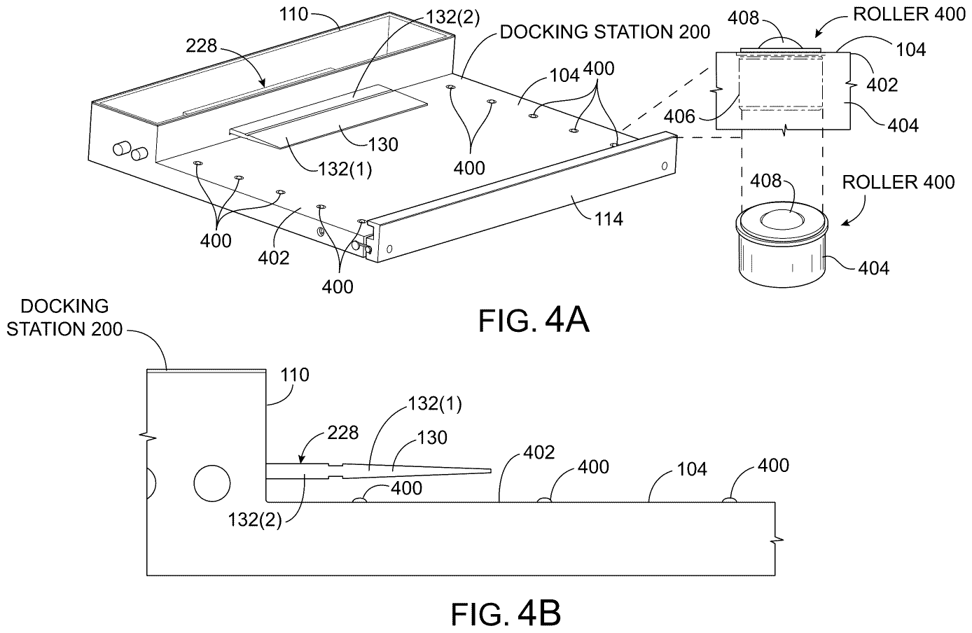

It may also be desired to provide a way to reduce friction when the electronic device 106 is moved about the platform 104 of the docking station 200 in FIGS. 2A-2E, such as when the front retaining member 114 is moved towards the rear member 110 to move the electronic device 106 back towards the rear member 110. In this regard, FIGS. 4A and 4B are front, side perspective and side views of the docking station 200 in FIGS. 2A-2E, further illustrating rollers 400 disposed in and exposed from a top surface 402 of the platform 104 to facilitate the insertion and traversing of the electronic device 106 on the platform 104 in the docking station 200. Note that although the rollers 400 in FIGS. 4A and 4B are provided in the docking station 200 in FIGS. 2A-2E, the rollers 400 in FIGS. 4A and 4B could also be provided in the docking station 100 in FIGS. 1A-1-1F. As shown in FIG. 4A, the rollers 400 include a housing 404 that is disposed in openings 406 in the platform 104. A ball 408 (e.g., a plastic ball, a metal ball) is partially retained in the housing 404 and partially exposed from the housing 404 and the top surface 402 of the platform 104. The balls 408 of the rollers 400 are configured to be able to rotate within the housing 404 to facilitate reducing friction in movement of the electronic device 106 on the top surface 402 of the platform 104.

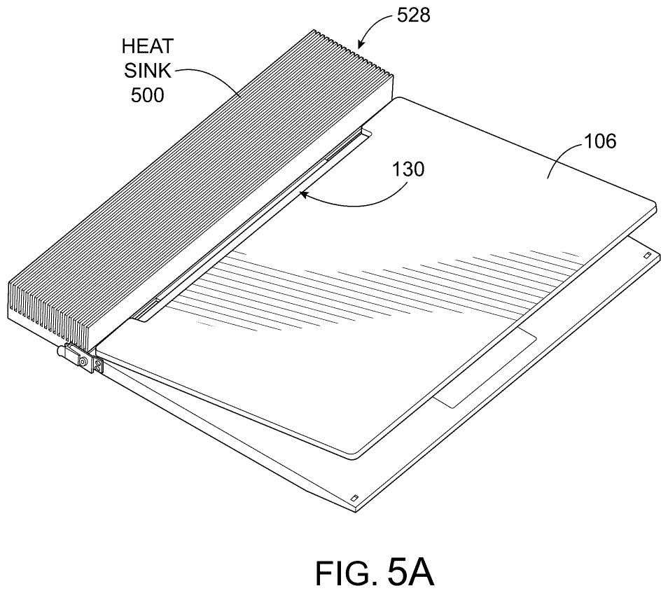

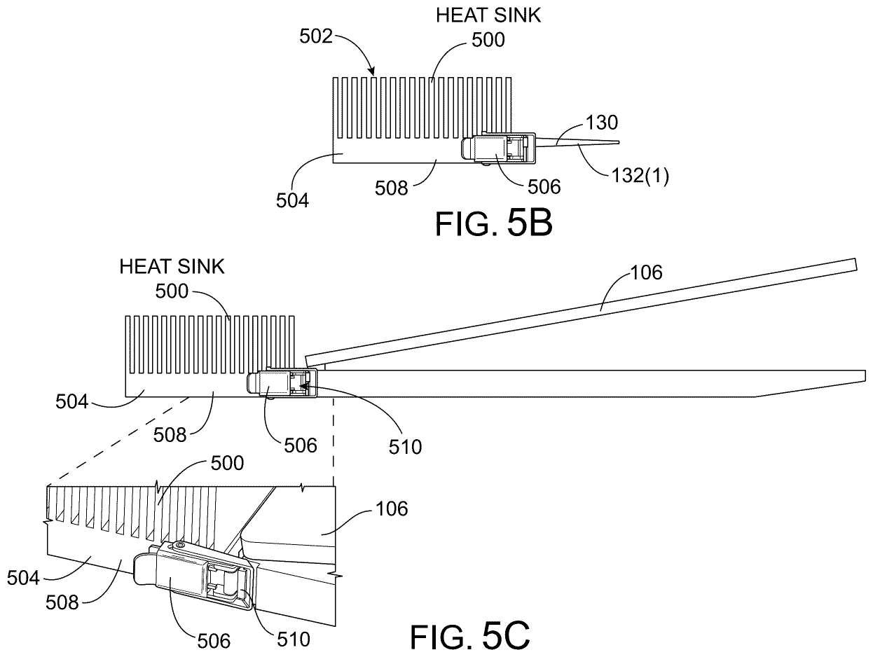

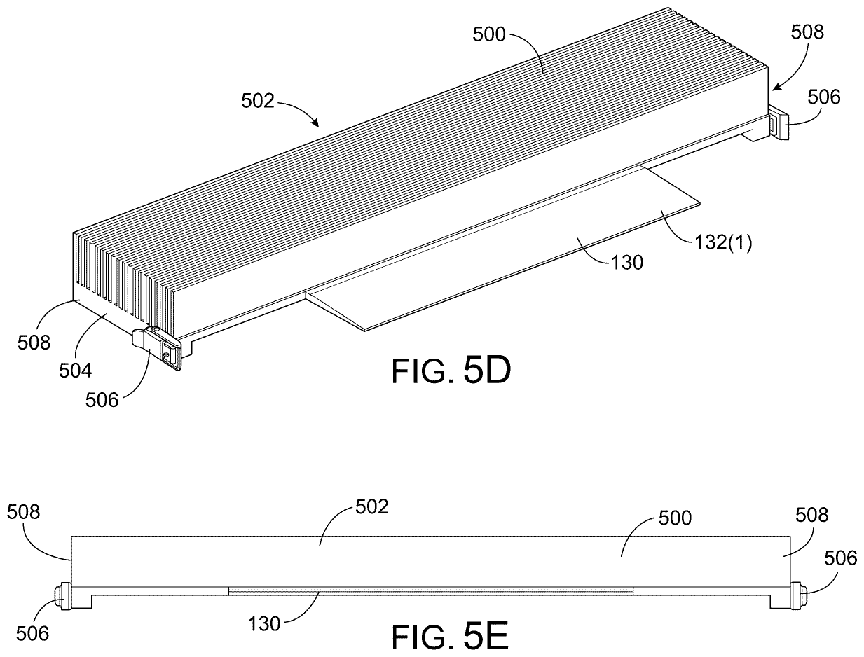

FIG. 5A is a side perspective view of an alternative heat dissipation device 528 that can be employed in a docking station, like the docking station 100 in FIGS. 1A-1-1F. As shown in FIG. 5A, the heat dissipation device 528 includes an external heat sink 500 thermally coupled to the metal plate 130 like in FIGS. 1A-1-1F and 2A-2E to provide enhanced heat dissipation for a docked electronic device, such as the electronic device 106. In this manner, the heat sink 500 provides a similar heat dissipation function to the liquid transfer tube 206 in the docking station 200 in FIGS. 2A-2E, but the heat sink 500 dissipates heat without liquid cooling. The heat sink 500 can be disposed in a rear member of a docking station like the liquid transfer tube 206 is disposed in the rear member 110 of the docking station 200 in FIGS. 2A-2E.

FIGS. 5B and 5C are side and close-up side views of the external heat sink 500 of the heat dissipation device 528 in FIG. 5A. FIGS. 5D and 5E are side perspective and front views of the external heat sink 500 of the heat dissipation device 528 in FIGS. 5A-5C illustrating more detail of the heat sink 500 coupled to the metal plate 130. As shown in FIGS. 5B-5E, the heat sink 500 includes metal fins 502 that extend upward in the first, vertical direction (Z-axis direction) from a metal block 504. Also, in this example, as shown in FIGS. 5B and 5D-5E, the heat sink 500 is shown coupled to the metal plate 130. In this example, as shown in FIGS. 5B-5E, optional latches 506 are also coupled to side surfaces 508 of the heat sink 500. The latches 506 may be provided on one or each side of the heat sink 500. As shown in FIG. 5C, the latches 506 are configured to engage with a complementary protrusion 510 on the sides of the electronic device 106 to further secure the electronic device 106 to a docking station like the docking station 100 in FIGS. 1A-1-1F, and to retain the metal plate 130 in the internal cavity 134 of the electronic device 106 like shown in FIGS. 1A-1-1F for example.

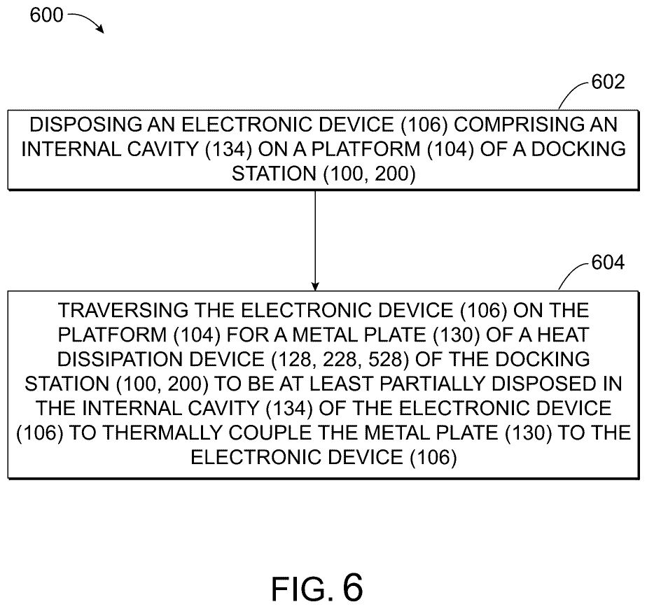

FIG. 6 is a flowchart illustrating an exemplary process 600 of docking an electronic device in a docking station that includes a heat dissipation device in the form of a metal plate configured to be at least partially received by an internal cavity of an electronic device disposed on the platform and docked/to be docked in the docking station, to dissipate heat generated by the electronic device, including, but not limited to, the docking stations and heat dissipation devices in FIGS. 1A-1-5E. The process 600 in FIG. 6 can be performed in reference, but without limitation to the docking stations 100, 200 in FIGS. 1A-1-4B, and in regard to thermally coupling an electronic device, such as the electronic device 106, to a heat dissipation device in the docking station, such as the heat dissipation devices 128, 228, 528 in FIGS. 1A-1-2E and 5A-5E. The process 600 in FIG. 6 is discussed with regard to the docking stations 100, 200 in FIGS. 1A-1-4B, and employing any of the heat dissipation devices 128, 228, 528 in FIGS. 1A-1-2E and 5A-5E, but such is not limiting.

In this regard, the process 600 in FIG. 6 can include disposing an electronic device 106 comprising an internal cavity 134 on a platform 104 of a docking station 100, 200 (block 602 in FIG. 6). The process 600 can also then include traversing the electronic device 106 on the platform 104 for a metal plate 130 of a heat dissipation device 128, 228, 528 of the docking station 100, 200 to be at least partially disposed in the internal cavity 134 of the electronic device 106 to thermally couple the metal plate 130 to the electronic device 106 (block 604 in FIG. 6).

It should be understood that the terms “first,” “second,” “third,” etc., where used herein, are relative terms that may be used to distinguish between similarly named elements and are not meant to limit or imply a strict orientation and/or order unless otherwise specified. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example. For example, if a particular object that is discussed as at “top,” or “upper” or “above” another object, and such particular object is flipped 180 degrees, then such particular object would then be oriented as at “bottom,” or “lower” or “below” such other object.

An object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

A docking station that includes a housing with a platform configured to support an electronic device, wherein the docking station also includes a heat dissipation device in the form of a metal plate configured to be at least partially received by an internal cavity of an electronic device disposed on the platform and docked/to be docked in the docking station, to dissipate heat generated by the electronic device, including, but not limited to, the docking stations 100, 200 in FIGS. 1A-4B with their heat dissipation devices 128, 228, 528 FIGS. 1A-1-5E, and that can be used to dock an electronic device to provide cooling for the electronic device according to a process, including, but not limited to, the processes 600 in FIG. 6, can be employed to dock an electronic device that includes a processor-based device or wireless device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, and a vehicle component.

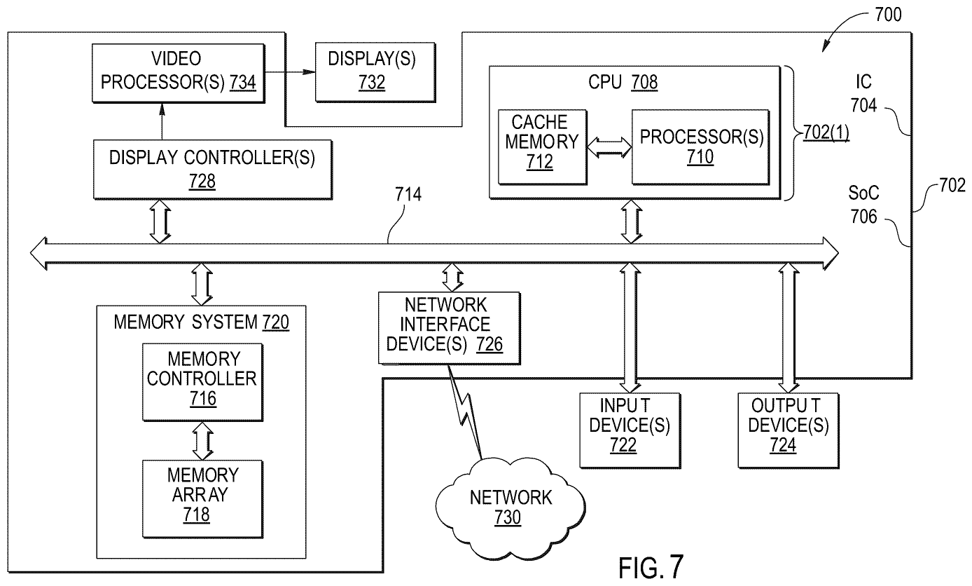

In this regard, FIG. 7 illustrates an example of a processor-based system 700 that can be an electronic device 702, such as the electronic device 106 in FIGS. 1A-1-5E, and that can be docked in a docking station that includes a housing with a platform configured to support an electronic device, wherein the docking station also includes a heat dissipation device in the form of a metal plate configured to be at least partially received by an internal cavity of an electronic device disposed on the platform and docked/to be docked in the docking station, to dissipate heat generated by the electronic device, including, but not limited to, the docking stations 100, 200 in FIGS. 1A-4B with their heat dissipation devices 128, 228, 528 FIGS. 1A-1-5E, and that can be used to dock an electronic device to provide cooling for the electronic device according to a process, including, but not limited to, the processes 600 in FIG. 6, and according to any aspects disclosed herein.

In this example, the processor-based system 700 may be formed as an IC 704 and as a system-on-a-chip (SoC) 706. In this example, the processor-based system 700 may be provided as or include a system-on-a-chip (SoC) 706. The processor-based system 700 includes a CPU 708 that includes one or more processors 710, which may also be referred to as CPU cores or processor cores. The CPU 708 may have cache memory 712 coupled to the processor(s) 710 for rapid access to temporarily stored data. The CPU 708 is coupled to a system bus 714 and can intercouple master and slave devices included in the processor-based system 700. As is well known, the CPU 708 communicates with these other devices by exchanging address, control, and data information over the system bus 714. For example, the CPU 708 can communicate bus transaction requests to a memory controller 716 as an example of a slave device. Although not illustrated in FIG. 7, multiple system buses 714 could be provided, wherein each system bus 714 constitutes a different fabric.

Other master and slave devices can be connected to the system bus 714. As illustrated in FIG. 7, these devices can include a memory system 720 that includes the memory controller 716 and a memory array(s) 718, one or more input devices 722, one or more output devices 724, one or more network interface devices 726, and one or more display controllers 728, as examples. Each of the memory system 720, the one or more input devices 722, the one or more output devices 724, the one or more network interface devices 726, and the one or more display controllers 728 can be provided in the same or different circuit packages. The input device(s) 722 can include any type of input device, including, but not limited to, input keys, switches, voice processors, etc. The output device(s) 724 can include any type of output device, including, but not limited to, audio, video, other visual indicators, etc. The network interface device(s) 726 can be any device configured to allow exchange of data to and from a network 730. The network 730 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 726 can be configured to support any type of communications protocol desired.

The CPU 708 may also be configured to access the display controller(s) 728 over the system bus 714 to control information sent to one or more displays 732. The display controller(s) 728 sends information to the display(s) 732 to be displayed via one or more video processors 734, which process the information to be displayed into a format suitable for the display(s) 732. The display(s) 732 can include any type of display, including, but not limited to, a cathode ray tube (CRT), a liquid crystal display (LCD), a plasma display, a light emitting diode (LED) display, etc.

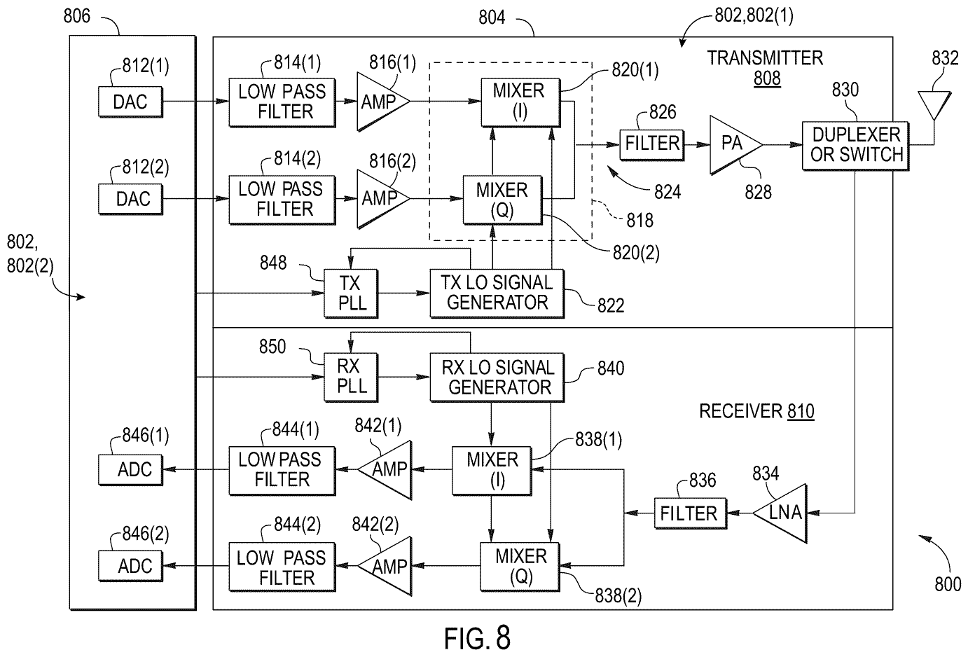

FIG. 8 illustrates an example of a wireless communications device 800 that can be an electronic device 802, 802(1), 802(2), such as the electronic device 106 in FIGS. 1A-1-5E, and that can be docked in a docking station that includes a housing with a platform configured to support an electronic device, wherein the docking station also includes a heat dissipation device in the form of a metal plate configured to be at least partially received by an internal cavity of an electronic device disposed on the platform and docked/to be docked in the docking station, to dissipate heat generated by the electronic device, including, but not limited to, the docking stations 100, 200 in FIGS. 1A-4B with their heat dissipation devices 128, 228, 528 FIGS. 1A-1-5E, and that can be used to dock an electronic device to provide cooling for the electronic device according to a process, including, but not limited to, the processes 600 in FIG. 6, and according to any aspects disclosed herein.

The wireless communications device 800 includes a transceiver 804 and a data processor 806. The data processor 806 may include a memory to store data and program codes. The transceiver 804 includes a transmitter 808 and a receiver 810 that support bi-directional communications. In general, the wireless communications device 800 may include any number of transmitters 808 and/or receivers 810 for any number of communication systems and frequency bands. All or a portion of the transceiver 804 may be implemented on one or more analog ICs, RF ICs (RFICs), mixed-signal ICs, etc.

The transmitter 808 or the receiver 810 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage in receiver 810. In the direct-conversion architecture, a signal is frequency-converted between RF and baseband in one stage. The super-heterodyne and direct-conversion architectures may use different circuit blocks and/or have different requirements. In the wireless communications device 800 in FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1), 812(2) for converting digital signals generated by the data processor 806 into I and Q analog output signals, e.g., I and Q output currents, for further processing.

Within the transmitter 808, lowpass filters 814(1), 814(2) filter the I and Q analog output signals, respectively, to remove undesired signals caused by the prior digital-to-analog conversion. Amplifiers (AMPs) 816(1), 816(2) amplify the signals from the lowpass filters 814(1), 814(2), respectively, and provide I and Q baseband signals. An upconverter 818 upconverts the I and Q baseband signals with I and Q transmit (TX) local oscillator (LO) signals from a TX LO signal generator 822 through mixers 820(1), 820(2) to provide an upconverted signal 824. A filter 826 filters the upconverted signal 824 to remove undesired signals caused by the frequency upconversion as well as noise in a receive frequency band. A power amplifier (PA) 828 amplifies the upconverted signal 824 from the filter 826 to obtain the desired output power level and provides a transmit RF signal. The transmit RF signal is routed through a duplexer or switch 830 and transmitted via an antenna 832.

In the receive path, the antenna 832 receives signals transmitted by base stations and provides a received RF signal, which is routed through the duplexer or switch 830 and provided to a low noise amplifier (LNA) 834. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. Downconversion mixers 838(1), 838(2) mix the output of the filter 836 with I and Q RX LO signals (i.e., LO_I and LO_Q) from an RX LO signal generator 840 to generate I and Q baseband signals. The I and Q baseband signals are amplified by AMPs 842(1), 842(2) and further filtered by lowpass filters 844(1), 844(2) to obtain I and Q analog input signals, which are provided to the data processor 806. In this example, the data processor 806 includes analog-to-digital converters (ADCs) 846(1), 846(2) for converting the analog input signals into digital signals to be further processed by the data processor 806.

In the wireless communications device 800 of FIG. 8, the TX LO signal generator 822 generates the I and Q TX LO signals used for frequency upconversion, while the RX LO signal generator 840 generates the I and Q RX LO signals used for frequency downconversion. Each LO signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. A docking station, comprising:
   a housing comprising a platform configured to support an electronic device, and a rear member that extends upward from a rear side of the platform; and
   a heat dissipation device, comprising:
      a metal plate that extends from the rear member of the housing towards the platform,
   the metal plate configured to be at least partially disposed in an internal cavity of an electronic device disposed on the platform to thermally couple the metal plate to the electronic device.
2. The docking station of clause 1, wherein the heat dissipation device further comprises a cooling device thermally coupled to the metal plate, the cooling device configured to dissipate heat conducted by the metal plate.
3. The docking station of clause 2, wherein the metal plate comprises:
   a first metal plate portion configured to be at least partially disposed in the internal cavity of the electronic device disposed on the platform; and
   a second metal plate portion configured to be external from the internal cavity of the electronic device when the first metal plate portion is at least partially received by the internal cavity of the electronic device; and
   the cooling device thermally coupled to the second metal plate portion.
4. The docking station of clause 3, wherein the first metal plate portion has a triangular-shaped side cross-sectional profile.
5. The docking station of any of clauses 2-4, wherein the cooling device comprises a liquid cooling device coupled to the metal plate,
   the liquid cooling device configured to carry a liquid thermally coupled to the metal plate to dissipate heat conducted by the metal plate.
6. The docking station of clause 5, wherein the liquid cooling device comprises a liquid transfer tube comprising:
   an inlet configured to receive the liquid in a cooled state; and
   an outlet configured to expel the liquid in a heated state from the heat thermally conducted by the metal plate from the electronic device;
   the liquid transfer tube configured to carry the liquid from the inlet in the cooled state to the outlet in the heated state from the heat conducted by the metal plate.
7. The docking station of clause 5 or 6, wherein:
   the metal plate comprises:
      a first metal plate portion configured to be at least partially disposed in the internal cavity of the electronic device disposed on the platform; and
      a second metal plate portion configured to be external from the internal cavity of the electronic device when the first metal plate portion is at least partially received by the internal cavity of the electronic device; and
   the liquid cooling device is coupled to the second metal plate portion.
8. The docking station of clause 7, wherein the liquid transfer tube extends in a loop between a first side of the second metal plate portion adjacent to the rear member of the housing, towards a second side of the second metal plate portion opposite the first side of the second metal plate portion.
9. The docking station of clause 7 or 8, wherein the liquid cooling device is integrated into the second metal plate portion as a single metal component.
10. The docking station of any of clauses 2-4, wherein:
the metal plate comprises:
   a first metal plate portion configured to be at least partially disposed in the internal cavity of the electronic device disposed on the platform; and
   a second metal plate portion configured to be external from the internal cavity of the electronic device when the first metal plate portion is at least partially received by the internal cavity of the electronic device; and
the heat dissipation device further comprises a heat sink coupled to the second metal plate portion.
11. The docking station of clause 10, wherein the heat sink comprises:
   a metal block coupled to the second metal plate portion; and
   a plurality of metal fins coupled to the metal block that extend upward from the metal block in a direction away from the rear member of the housing.
12. The docking station of any of clauses 1-11, wherein:
   the rear member of the housing is coupled to the rear side of the platform;
   the housing further comprises:
      a front retaining member; and
      a latching mechanism coupled to the front retaining member of the housing and a front side of the platform opposite the rear member of the housing;
      the latching mechanism configured to allow the front retaining member to be traversed about the rear member of the housing; and
   the front retaining member configured to engage with a front side of the electronic device disposed on the platform to traverse towards the rear member of the housing to secure the electronic device between the front retaining member and the rear member of the housing.
13. The docking station of clause 12, wherein the front retaining member comprises a slot configured to receive the front side of the electronic device disposed on the platform.
14. The docking station of clause 12 or 13, wherein the latching mechanism comprises a spring-loaded plunger configured to be locked to the front side of the platform when the front retaining member is moved in a direction towards the front side to the platform to secure the electronic device on the platform between the front retaining member and the rear member of the housing.
15. The docking station of clause 14, wherein the spring-loaded plunger is further configured to be unlocked from the front side of the platform to allow the front retaining member of the housing to move in a direction away from the front side of the platform.
16. The docking station of any of clauses 1-15, further comprising one or more latches each coupled to a side of the metal plate and each configured to engage with a complementary latch receiver on a side of the electronic device disposed on the platform, to secure the metal plate at least partially received by the internal cavity of the electronic device.
17. The docking station of any of clauses 1-16, wherein the platform comprises a first surface configured to support the electronic device; and
   further comprising one or more rollers exposed from the first surface of the platform.
18. The docking station of any of clauses 1-17, wherein the electronic device is selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; and a vehicle component.
19. A system, comprising:
   an electronic device comprising an internal cavity; and
   a docking station, comprising:
      a housing comprising a platform configured to support an electronic device, and a rear member that extends upward from a rear side of the platform; and
      a heat dissipation device, comprising:
         a metal plate that extends from the rear member of the housing towards the platform,
         the metal plate configured to be at least partially disposed in the internal cavity of the electronic device disposed on the platform to thermally couple the metal plate to the electronic device.
20. A docking station system, comprising:
   a docking station, comprising:
      a housing comprising a platform configured to support an electronic device, and a rear member that extends upward from a rear side of the platform; and
      a heat dissipation device, comprising:
         a metal plate that extends from the rear member of the housing towards the platform,
         the metal plate configured to be at least partially disposed in an internal cavity of an electronic device disposed on the platform to thermally couple the metal plate to the electronic device; and
         a liquid cooling device coupled to the metal plate, the liquid cooling device configured to carry a liquid thermally coupled to the metal plate to dissipate heat conducted by the metal plate; and
   a liquid cooling station comprising:
      a liquid reservoir configured to store the liquid;
      a cooling device configured to cool the liquid in the liquid reservoir; and
      a pump coupled to the liquid reservoir;
      the pump configured to:
   pump the liquid in a cooled state from the liquid reservoir to the liquid cooling device; and
   receive the liquid in a heated state from the liquid cooling device.
21. The docking station system of clause 20, wherein:
   the liquid cooling device comprises a liquid transfer tube coupled to the metal plate, the liquid transfer tube comprising:
      an inlet configured to receive the liquid in the cooled state; and
      an outlet configured to expel the liquid in the heated state from the heat thermally conducted by the metal plate from the electronic device,
      the liquid transfer tube configured to carry the liquid from the inlet in the cooled state to the outlet in the heated state from the heat conducted by the metal plate; and
   the pump of the liquid cooling station further comprises:
      a pump outlet configured to be coupled to the inlet of the liquid transfer tube; and
      a pump inlet configured to be coupled to the outlet of the liquid transfer tube;
   the pump configured to:
      pump the liquid in the cooled state from the liquid reservoir to the pump outlet coupled to the inlet of the liquid transfer tube; and
      receive the liquid in the heated state through the pump inlet coupled to the outlet of the liquid transfer tube.

What is claimed is:

1. A docking station, comprising:
a housing comprising a platform configured to support an electronic device, and a rear member that extends upward from a rear side of the platform; and
a heat dissipation device, comprising:
a metal plate that extends from the rear member of the housing towards the platform,
the metal plate configured to be at least partially disposed in an internal cavity of an electronic device disposed on the platform to thermally couple the metal plate to the electronic device.

2. The docking station of claim 1, wherein the heat dissipation device further comprises a cooling device thermally coupled to the metal plate, the cooling device configured to dissipate heat conducted by the metal plate.

3. The docking station of claim 2, wherein the metal plate comprises:
a first metal plate portion configured to be at least partially disposed in the internal cavity of the electronic device disposed on the platform; and
a second metal plate portion configured to be external from the internal cavity of the electronic device when the first metal plate portion is at least partially received by the internal cavity of the electronic device; and
the cooling device thermally coupled to the second metal plate portion.

4. The docking station of claim 3, wherein the first metal plate portion has a triangular-shaped side cross-sectional profile.

5. The docking station of claim 2, wherein the cooling device comprises a liquid cooling device coupled to the metal plate,
the liquid cooling device configured to carry a liquid thermally coupled to the metal plate to dissipate heat conducted by the metal plate.

6. The docking station of claim 5, wherein the liquid cooling device comprises a liquid transfer tube comprising:
an inlet configured to receive the liquid in a cooled state; and
an outlet configured to expel the liquid in a heated state from the heat thermally conducted by the metal plate from the electronic device;
the liquid transfer tube configured to carry the liquid from the inlet in the cooled state to the outlet in the heated state from the heat conducted by the metal plate.

7. The docking station of claim 5, wherein:
the metal plate comprises:
a first metal plate portion configured to be at least partially disposed in the internal cavity of the electronic device disposed on the platform; and
a second metal plate portion configured to be external from the internal cavity of the electronic device when the first metal plate portion is at least partially received by the internal cavity of the electronic device; and
the liquid cooling device is coupled to the second metal plate portion.

8. The docking station of claim 7, wherein the liquid transfer tube extends in a loop between a first side of the second metal plate portion adjacent to the rear member of the housing, towards a second side of the second metal plate portion opposite the first side of the second metal plate portion.

9. The docking station of claim 7, wherein the liquid cooling device is integrated into the second metal plate portion as a single metal component.

10. The docking station of claim 2, wherein:
the metal plate comprises:
a first metal plate portion configured to be at least partially disposed in the internal cavity of the electronic device disposed on the platform; and
a second metal plate portion configured to be external from the internal cavity of the electronic device when the first metal plate portion is at least partially received by the internal cavity of the electronic device; and
the heat dissipation device further comprises a heat sink coupled to the second metal plate portion.

11. The docking station of claim 10, wherein the heat sink comprises:
a metal block coupled to the second metal plate portion; and
a plurality of metal fins coupled to the metal block that extend upward from the metal block in a direction away from the rear member of the housing.

12. The docking station of claim 1, wherein:
the rear member of the housing is coupled to the rear side of the platform;
the housing further comprises:
a front retaining member; and
a latching mechanism coupled to the front retaining member of the housing and a front side of the platform opposite the rear member of the housing;
the latching mechanism configured to allow the front retaining member to be traversed about the rear member of the housing; and
the front retaining member configured to engage with a front side of the electronic device disposed on the platform to traverse towards the rear member of the housing to secure the electronic device between the front retaining member and the rear member of the housing.

13. The docking station of claim 12, wherein the front retaining member comprises a slot configured to receive the front side of the electronic device disposed on the platform.

14. The docking station of claim 12, wherein the latching mechanism comprises a spring-loaded plunger configured to be locked to the front side of the platform when the front retaining member is moved in a direction towards the front side to the platform to secure the electronic device on the platform between the front retaining member and the rear member of the housing.

15. The docking station of claim 14, wherein the spring-loaded plunger is further configured to be unlocked from the front side of the platform to allow the front retaining member of the housing to move in a direction away from the front side of the platform.

16. The docking station of claim 1, further comprising one or more latches each coupled to a side of the metal plate and each configured to engage with a complementary latch receiver on a side of the electronic device disposed on the platform, to secure the metal plate at least partially received by the internal cavity of the electronic device.

17. The docking station of claim 1, wherein the platform comprises a first surface configured to support the electronic device; and
further comprising one or more rollers exposed from the first surface of the platform.

18. The docking station of claim 1, wherein the electronic device is selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer;
a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; and a vehicle component.

19. A system, comprising:
an electronic device comprising an internal cavity; and
a docking station, comprising:
a housing comprising a platform configured to support an electronic device, and a rear member that extends upward from a rear side of the platform; and
a heat dissipation device, comprising:
a metal plate that extends from the rear member of the housing towards the platform,
the metal plate configured to be at least partially disposed in the internal cavity of the electronic device disposed on the platform to thermally couple the metal plate to the electronic device.

20. A docking station system, comprising:
a docking station, comprising:
a housing comprising a platform configured to support an electronic device, and a rear member that extends upward from a rear side of the platform; and
a heat dissipation device, comprising:
a metal plate that extends from the rear member of the housing towards the platform,
the metal plate configured to be at least partially disposed in an internal cavity of an electronic device disposed on the platform to thermally couple the metal plate to the electronic device; and
a liquid cooling device coupled to the metal plate, the liquid cooling device configured to carry a liquid thermally coupled to the metal plate to dissipate heat conducted by the metal plate; and
a liquid cooling station comprising:
a liquid reservoir configured to store the liquid;
a cooling device configured to cool the liquid in the liquid reservoir; and
a pump coupled to the liquid reservoir;
the pump configured to:
pump the liquid in a cooled state from the liquid reservoir to the liquid cooling device; and
receive the liquid in a heated state from the liquid cooling device.

21. The docking station system of claim 20, wherein:
the liquid cooling device comprises a liquid transfer tube coupled to the metal plate, the liquid transfer tube comprising:
an inlet configured to receive the liquid in the cooled state; and
an outlet configured to expel the liquid in the heated state from the heat thermally conducted by the metal plate from the electronic device,
the liquid transfer tube configured to carry the liquid from the inlet in the cooled state to the outlet in the heated state from the heat conducted by the metal plate; and
the pump of the liquid cooling station further comprises:
a pump outlet configured to be coupled to the inlet of the liquid transfer tube; and
a pump inlet configured to be coupled to the outlet of the liquid transfer tube;
the pump configured to:
pump the liquid in the cooled state from the liquid reservoir to the pump outlet coupled to the inlet of the liquid transfer tube; and
receive the liquid in the heated state through the pump inlet coupled to the outlet of the liquid transfer tube.
